(19) United States
(12) Patent Application Publication
(10) Pub. No.: US 2011/0221519 A1
(43) Pub. Date: Sep. 15, 2011

(54) SEMICONDUCTOR INTEGRATED CIRCUIT AND HIGH FREQUENCY MODULE USING THE SAME

(75) Inventors: Kaoru KATOH, Hitachinaka (JP); Shigeki KOYA, Tokyo (JP); Yasushi SHIGENO, Kanagawa (JP); Akishige NAKAJIMA, Kanagawa (JP); Takashi OGAWA, Tokyo (JP)

(73) Assignee: RENESAS ELECTRONICS CORPORATION, Kanagawa (JP)

(21) Appl. No.: 13/043,626

(22) Filed: Mar. 9, 2011

(30) Foreign Application Priority Data
Mar. 15, 2010 (JP) 2010-057033

(51) Int. Cl. H03B 1/04

(52) U.S. Cl. 327/558; 327/552

(57) ABSTRACT

The present invention reduces harmonic components of an RF transmission output signal. In the semiconductor integrated circuit which the present invention provides, a transmission switch of an antenna switch thereof includes transmission field effect transistors whose S-D current paths are coupled between a transmission terminal and an input/output terminal and whose gate terminals are coupled to a transmission control terminal. A reception switch of the antenna switch includes reception field effect transistors whose S-D current paths are coupled between the input/output terminal and a reception terminal and whose gate terminals are coupled to a reception control terminal. The transmission and reception n-channel MOS field effect transistors are respectively formed in a silicon-on-insulator structure. A substrate voltage of a voltage generator, set to reducing each harmonic component of the antenna switch, is supplied to the transmission control terminal and the reception coupled to a support silicon substrate having the SOI structure.

### CROSS-REFERENCE TO RELATED APPLICATIONS

The present application claims priority from Japanese patent application JP 2010-057033 filed on Mar. 15, 2010, the content of which is hereby incorporated by reference into this application.

### BACKGROUND

The present invention relates to a semiconductor integrated circuit including an antenna switch, and a high frequency (i.e., radio frequency) module with the semiconductor integrated circuit built therein. The present invention relates particularly to a technology useful in reducing each harmonic component of an RF (Radio Frequency) transmission output signal.

As an antenna switch for a transmission/reception switch used in transmitting/receiving devices such as a cellular phone terminal, a WLAN, etc., there has generally been known an antenna switch using PIN diodes. In recent years, however, an FET (Field Effect Transistor), particularly, an HEMT (High Electron Mobility Transistor) of a hetero junction structure having a low on resistance has been used in the antenna switch. In order to realize a heterojunction, however, a relatively expensive compound semiconductor manufacturing process is required. Further, SOI-MOSFETs to which a silicon semiconductor manufacturing process is applicable are on the recent trend to be used as switching transistors in order to meet demands for a reduction in manufacturing cost and the like. Incidentally, SOI is an abbreviation of Silicon On Insulator.

The antenna switch can also be integrated as a monolithic microwave integrated circuit (MMIC) according to the use of FETs. When SOI-MOSFETs corresponding to n-channel depletion type FETs are used in the antenna switch, a high potential difference greater than or equal to a threshold voltage is applied between the gate and source of each FET to be turned ON, whereas a low potential difference less than or equal to a threshold voltage is applied between the gate and source of each FET to be turned OFF.

In the antenna switch configured using the SOI-MOSFETs, a silicon (Si) substrate is used as a support substrate. On the other hand, in an antenna switch configured using SOS-MOSFETs, sapphire is used as a support substrate. It is therefore possible to reduce a substrate capacitance associated with a source-to-drain diffusion layer and reduce secondary harmonic distortion. Incidentally, SOS is an abbreviation of Silicon On Sapphire.

Further, a patent document 1 has described that in order to lighten the effects of a nonlinear response, harmonic distortion and inter modulation distortion by eliminating or controlling an electric charge opposite in polarity to each carrier, accumulated in a channel region near a gate oxide film of each SOI(SOS)-MOSFET used in an RF switch, an accumulated charge sink (ACS) is electrically coupled to the body of the SOI-MOSFET. In an n-type channel SOI-MOSFET, a source and drain thereof are formed by high-concentration ion-implantation of an n-type dopant in a silicon layer formed over an insulation board. The silicon layer between the source and drain is doped with a p-type dopant in low concentration, thereby forming a body thereof. A gate comprised of a gate oxide film or a layer of a metal or polysilicon is formed over the body. Directly underneath the gate oxide film, an electrical contact region comprised of a P+ region is coupled to an accumulated charge sink (ACS) comprised of a P− region electrically coupled to the body comprised of the P− region between the source and drain. An ACS terminal is electrically coupled to the electrical contact region. The ACS terminal is coupled to a gate terminal directly or via a diode, or an ACS bias voltage generated from a control circuit is supplied to the ACS terminal, thereby making it possible to eliminate the above accumulated charge through the ACS terminal.

Furthermore, the patent document 1 has described an SPDT (Single Pole Double Throw) RF switch circuit and also has described that a first reception switch MOSFET is coupled between a common node and a first RF input node, a second reception switch MOSFET is coupled between the common node and a second RF input node, a first shunt switch MOSFET is coupled between the first RF input node and a ground potential and a second shunt switch MOSFET is coupled between the second RF input node and the ground potential, and these switch MOSFETs are configured by SOI-MOSFETs. A first control signal is supplied to a gate terminal of the first reception switch MOSFET and a gate terminal of the second shunt switch MOSFET. A second control signal is supplied to a gate terminal of the second reception switch MOSFET and a gate terminal of the first shunt switch MOSFET. Further, a first ACS control signal is supplied to an ACS terminal of the first reception switch MOSFET and an ACS terminal of the second shunt switch MOSFET. A second ACS control signal is supplied to an ACS terminal of the second reception switch MOSFET and an ACS terminal of the first shunt switch MOSFET.

A high frequency switch circuit in which general MOSFETs called bulk-type MOSFETs other than the SOI-MOSFETs described in the patent document 1 are used as switches, has been described in a patent document 2. When a control signal of a high level is inputted to the gates of through FETs and shunt FETs to turn them ON, all transistors are respectively brought to an OFF state by a parallel coupling of resistors and transistors coupled between their gates and a control signal terminal and a parallel coupling of resistors and transistors coupled between their backgates and a ground potential. Thus, a high frequency signal is transferred from the drain sides of the through FETs and the shunt FETs to the source sides thereof with a low loss. On the other hand, when a control signal of a low level is inputted to the gates of the through FETs and the shunt FETs to turn them OFF, all the transistors are respectively brought to an ON state by the parallel coupling of the resistors and transistors coupled between the gates and the control signal terminal and the parallel coupling of the resistors and transistors coupled between the backgates and the ground potential. Thus, since a high frequency signal is transferred from the drain sides of the through FETs and the shunt FETs to the control signal terminal and the ground potential, the amount of transfer thereof to the source sides can be reduced and the isolation characteristics at OFF can be improved.

Further, a high frequency switch circuit in which Si-FETs of MOS or junction type other than the SOI-MOSFETs described in the patent document 1 are configured as switches, has been described in a patent document 3. In the high frequency switch circuit, a first transistor is coupled between a common node and a first RF terminal, a second transistor is coupled between the common node and a second RF terminal, a third transistor is coupled between the first RF terminal and a ground potential, and a fourth transistor is coupled between the second RF terminal and the ground potential. A low level voltage is supplied to the gate of the first transistor and the gate of the fourth transistor to turn them OFF. A high level voltage is supplied to the gate terminal of the second transistor and the gate of the third transistor to turn them ON. Since resistors are respectively coupled between the backgates of all the first to fourth transistors and the ground potential, it is possible to reduce a leakage of a high frequency signal from each of the backgates of the turned-off first through fourth transistors to the ground potential.

A switch circuit device in which an insertion loss and isolation characteristics have been improved, has been described in a patent document 4. The switch circuit device includes two n-channel MOSFETs of which the gates are coupled in common and the drain-to-source paths are coupled in series, p-channel MOSFETs having gates coupled to the gates of the two n-channel MOSFETs and drains coupled to a common connection node of the two n-channel MOSFETs, and a voltage switching circuit for selecting the voltage applied to the source of each p-channel MOSFET in response to a control voltage applied to the gate thereof. In the switch circuit device, the backgates of the two n-channel MOSFETs are grounded and a power supply voltage Vdd is applied to the backgate of the p-channel MOSFET.

Further, a patent document 5 has described that in order to reduce harmonic distortion of track and hold circuits each including a MOS transistor switch and a hold capacitor, a bias voltage generated by a constant voltage circuit comprised of a memory and a digital-analog converter is supplied to a bulk terminal (substrate terminal) of the MOS transistor switch. With respect to a sample of each individual track and hold circuit or a sample for each manufacturing lot, the relationship between a bias voltage of an actual bulk terminal and distortion is examined and an optimum point is stored in the memory.
Patent Document 1:
Japanese Patent Application Publication No. 2009-500868
Patent Document 2:
Japanese Unexamined Patent Publication No. 2008-270964
Patent Document 3:
Japanese Unexamined Patent Publication No. Hei 10(1998)-242826
Patent Document 4:
Japanese Unexamined Patent Publication No. 2007-329646
Patent Document 5:
Japanese Unexamined Patent Publication No. 2001-126492

### SUMMARY

Since the expensive compound semiconductor manufacturing process is not required for the antenna switch as mentioned above, the manufacturing cost can be reduced by using the SOI-MOSFETs to which the silicon semiconductor manufacturing process is applicable.

A study of the present inventors prior to the present invention has, however, revealed the problem that when SOI-MOSFETs are used in an antenna switch, harmonic distortion increases as compared with compound semiconductor transistors.

That is, when the antenna switch carries out a transmission operation, a transmission switch circuit is brought to an ON state. On the other hand, the voltage dependence of an off capacitance Coff of a reception switch circuit brought to an OFF state upon the transmission operation becomes a cause of the occurrence of harmonic distortion. Since the transmission switch circuit is in the ON state during the transmission operation, a transmission signal of relatively large amplitude applied to a transmission terminal is supplied to an antenna terminal via the transmission switch circuit. Therefore, the transmission signal of large amplitude is applied even to the reception switch circuit placed in the OFF state coupled between the antenna terminal and a reception terminal. Since the reception switch circuit placed in the OFF state has an off capacitance Coff comprised of a parasitic capacitive element such as a switch transistor or the like for the reception switch circuit, a transmission signal of large amplitude is applied to the off capacitance Coff. Accordingly, the voltage dependence of the off capacitance Coff determines the harmonic distortion of the antenna switch.

FIG. 6 is a diagram showing a device structure of an SOI-MOSFET that configures an antenna switch examined by the present inventors prior to the present invention.

In the SOI-MOSFET shown in FIG. 6 in a manner similar to the SOI-MOSFET described in the patent document 1, a buried silicon dioxide film layer Box used as an insulator (I) is formed over the surface of a silicon substrate (Si)Sub used as a support substrate. A silicon layer Si_Ly is formed over the surface (On) of the buried silicon dioxide film layer Box. The silicon layer Si_Ly has been doped with a p-type dopant in low concentration from the beginning in order to form an n-channel SOI-MOSFET.

A gate oxide film G_Ox and a gate electrode G_EI of a polysilicon layer are patterned at the surface of the silicon layer Si_Ly. Thereafter, source and drain regions SC and DR of an n-type impurity region are formed in the silicon layer Si_Ly by ion implantation using n-type dopants with the patterned gate oxide film G_Ox and gate electrode G_EI as masks. The p-type-doped silicon layer Si_Ly held by the source region SC and the drain region DR therebetween directly underneath the gate oxide film G_Ox functions as a body (B) called “backgate”. A white portion DP of the body (B) is a depletion layer. Holes taken as carriers do not exist inside the depletion layer DP, but the nucleus of each ionized p-type dopant exists therein. Accordingly, a portion other than the depletion layer DP in the p-type-doped silicon layer Si_Ly held by the source region SC and the drain region DR therebetween directly underneath the gate oxide film G_Ox functions as an electrically neutral body (B). That is, the amount of a positive charge due to holes as carriers and the amount of a negative charge due to the nucleus of each ionized p-type dopant are balanced inside the electrically neutral body (B).

The following parasitic capacitances exist in the SOI-MOSFET of the device structure shown in FIG. 6.

First, a series coupling of a source-to-drain MOS parasitic capacitance Cgs comprised of the source region SC of the n-type impurity region, the gate oxide film G_Ox and the gate electrode G_EI and a gate-to-drain MOS parasitic capacitance Cgd comprised of the gate electrode G_EI, the gate oxide film G_Ox and the drain region DR of the n-type impurity region exists between a source electrode 602(S) and a drain electrode 603(D).

Next, a source-to-drain parasitic capacitance Cds comprised of the source region SC of the n-type impurity region, the depletion layer DP and the drain region DR of the n-type impurity region exist between the source electrode 602(S) and the drain electrode 603(D).

Then, a series coupling of a source-to-body parasitic capacitance Cbs comprised of the source region SC of the n-type impurity region, the depletion layer DP and the body (B) and a body-to-drain parasitic capacitance Cbd comprised of the body (B), the depletion layer DP and the drain region DR of the n-type impurity region exists between the source electrode 602(S) and the drain electrode 603(D).

Further, a source-to-substrate parasitic capacitance Cssub comprised of the source region SC of the n-type impurity region, the buried silicon dioxide film layer Box and the silicon substrate (Si)Sub exists between the source electrode 602(S) and the silicon substrate (Si)Sub. A body (B)-to-substrate parasitic capacitance Cbsub comprised of the body (B), the buried silicon dioxide film layer Box and the silicon substrate (Si)Sub exists between the body (B) and the silicon substrate (Si)Sub. Further, a drain-to-substrate parasitic capacitance Cdsub comprised of the drain region of the n-type impurity region, the buried silicon dioxide film layer Box and the silicon substrate (Si)Sub exists between the drain electrode 603(D) and the silicon substrate (Si)Sub.

Finally, a parallel coupling of a substrate capacitor 31(Csub) and a substrate resistor 32(Rsub) exists between the main surface of the silicon substrate (Si)Sub and a silicon substrate electrode 604 at its back surface.

Since the film thickness of the buried silicon dioxide film layer Box is formed extremely large here, the values of the source-to-substrate parasitic capacitance Cssub, the body (B)-to-substrate parasitic capacitance Cbsub and the drain-to-substrate parasitic capacitance Cdsub can be ignored as small. The source-to-gate MOS parasitic capacitance Cgs and the gate-to-drain MOS parasitic capacitance Cgd can be made approximate to an equal capacitance value. The source-to-body parasitic capacitance Cbs and the body-to-drain parasitic capacitance Cbd can be made approximate to an equal capacitance value.

Accordingly, an off capacitance Coff between the source electrode 602(S) and the drain electrode 603(D) in an OFF state of the SOI-MOSFET of the device structure shown in FIG. 6 is given by the following equation:

$$Coff = \frac{1}{2} Cgs + Cds + \frac{1}{2} Cbs \qquad ( 1 )$$

1Cbs/2 of a third term of the above equation (1) is a parasitic capacitance between the electrically neutral body (B) and the source and drain. On the other hand, when a heterojunction-based switching transistor is used, the present transistor is formed in a compound semiconductor substrate of extremely high resistivity. Thus, a semiconductor region corresponding to the electrically neutral body of the antenna switch using SOI-MOSFETs does not exist in an antenna switch using a compound semiconductor in this case. As a result, when the SOI-MOSFETs are used in the antenna switch, harmonic distortion increases as compared with the antenna switch using the compound semiconductor because the third term of the above equation (1) is added to the off capacitance Coff.

As compared with the above equation (1), the following description is made in the patent document 1.

That is, according to the description of the patent document 1, low body impedance (p-type conductivity) due to the accumulated charge generated in the channel region adjacent to the gate oxide film by the gate bias voltage exists in the SOI-MOSFET placed in the OFF state. Accordingly, when the voltage is applied between the drain and source, a high frequency current flows through the SOI-MOSFET via the source-to-body junction capacitor, low body impedance (p-type conductivity) and drain-to-body junction capacitor. In order to solve it, an accumulated charge sink (ACS) is coupled to the body and the accumulated charge is eliminated by the ACS.

An influence on the voltage dependence of the capacitance and the off capacitance Coff due to a change in depletion layer width of each PN junction between the source-to-body junction capacitor and the drain-to-body junction capacitor corresponding to Cbs of the third term of the above equation (1) has been discussed in the patent document 1. However, the relative contribution of this influence is complicated and the overall improvement in the non-linear behavior of the off capacitance Coff is brought about by the elimination, removal and the like of the accumulated charge.

The patent document 1 has described that the gate-to-source capacitor and gate-to-drain capacitor corresponding to Cgs of the first term of the above equation (1) depend only slightly on the voltage and do not significantly contribute to the occurrence of harmonics and non-linear characteristics that adversely affect intermodulation distortion characteristics. On the other hand, the relative contribution of these capacitors is complicated and the overall improvement in the non-linear behavior of the off capacitance Coff is brought about by the elimination, removal and the like of the accumulated charge.

On the other hand, prior to the present invention, the present inventors have examined in detail, the voltage dependence of the off capacitance Coff given by the above equation (1) where the technology of eliminating the accumulated charge by the coupling of the accumulated charge sink (ACS) to the body, which has been described in the patent document 1, is applied to the SOI-MOSFET of the device structure shown in FIG. 6.

FIG. 8 is a diagram showing the voltage dependence of the off capacitance Coff given by the above equation (1) where the present inventors have applied the technology of eliminating the accumulated charge by coupling of the accumulated charge sink (ACS) to the body, which has been described in the patent document 1, to the SOI-MOSFET of the device structure shown in FIG. 6 prior to the present invention.

The dependence of the capacitance of the sum of 1Cgs/2 of the first term of the above equation (1) and Cds of the second term of the above equation (1) on a drain-to-source voltage Vds is shown on the left of FIG. 8. The capacitance of the sum becomes a minimum value when the drain-to-source voltage Vds is in the vicinity of zero volts, whereas the capacitance of the sum increases when the drain-to-source voltage Vds is in the neighborhood of +2.4 volts or −2.4 volts and thereafter becomes a saturated state. The cause of this mechanism is estimated as follows:

When the drain-to-source voltage Vds is in the vicinity of zero volts, each MOS structure of the source-to-gate MOS parasitic capacitance Cgs and gate-to-drain MOS parasitic capacitance Cgd coupled in series between the source electrode 602(S) and the drain electrode 603(D) is brought to a deplete state, and hence each MOS capacitance value becomes minimum. When the drain-to-source voltage Vds is in the vicinity of +2.4 volts or −2.4 volts, one of the source-to-gate MOS parasitic capacitance Cgs and gate-to-drain MOS parasitic capacitance Cgd coupled in series between the source electrode 602(S) and the drain electrode 603(D) and the other thereof are respectively brought to an accumulation state and an inversion state, and each MOS capacitance value increases more than the minimum value. Thereafter, one thereof becomes equivalent to an oxide film capacitance in the accumulation state, and the other thereof is brought to a strong inversion state in the inversion state, so that each MOS capacitance value does not increase, and hence they are brought to a saturated state.

Next, the source-to-drain parasitic capacitance Cds comprised of the SIS structure of the source region SC of the n-type impurity region, the depletion layer DP and the drain region DR of the n-type impurity region, lying between the source electrode 602(S) and the drain electrode 603(D) is maintained at a capacitance value approximately constant with respect to a change in the drain-to-source voltage Vds.

The dependence on the drain-to-source voltage Vds, of the capacitance of a series coupling of both the source-to-body parasitic capacitance Cbs comprised of the source region SC of the n-type impurity region, the depletion layer DP and the body (B), corresponding to 1Cbs/2 of the third term of the above equation (1) and the body-to-drain parasitic capacitance Cbd comprised of the body (B), the depletion layer DP and the drain region DR of the n-type impurity region is shown in the center of FIG. 8. The nonlinearity of the capacitance of the series coupling of the source-to-body parasitic capacitance Cbs and the body-to-drain parasitic capacitance Cbd is improved by the elimination of the accumulated charge by the application of the technology of eliminating the accumulated charge by the coupling of the accumulated charge sink (ACS) to the body, which has been described in the patent document 1. Therefore, the source-to-body parasitic capacitance Cbs shown in the center of FIG. 8 is maintained at a capacitance value approximately constant with respect to a change in the drain-to-source voltage Vds.

As a result, since the off capacitance Coff of the above equation (1) is determined by the sum total of both the capacitance of the sum of the first term 1Cgs/2 of the above equation (1) shown on the left of FIG. 8, and the second term Cds of the above equation (1), and the third term 1Cbs/2 of the above equation (1) shown in the center of FIG. 8, the voltage dependence of the off capacitance Coff of the above equation (1) is shown on the right of FIG. 8.

Even in the off capacitance Coff of the above equation (1) shown on the right of FIG. 8, the capacitance of the sum becomes a minimum value when the drain-to-source voltage Vds is in the vicinity of zero volts. On the other hand, when the drain-to-source voltage Vds is in the vicinity of +2.4 volts or −2.4 volts, the capacitance of the sum increases. Thus, since a large-amplitude transmission signal is applied to the reception switch circuit held in the OFF state during a transmission operation, and the off capacitance Coff increases with the increase in the drain-to-source voltage Vds, the harmonic distortion characteristic is degraded.

Further, in the technology of eliminating the accumulated charge by the coupling of the accumulated charge sink (ACS) to the body, which has been described in the patent document 1, the planar structure of each SOI-FET needs an electrical contact region of a P+ region for supplying a bias voltage to the body in addition to normally required source, drain and gate regions and a gate contact and an accumulated charge sink (ACS) of a P− region. The electrical contact region of the P+ region needs a manufacturing step to be added to the silicon semiconductor manufacturing process. On the other hand, the accumulated charge sink of the P− region has a problem that a by-chip occupied area increases in the planar structure of each SOI-FET. Since the antenna switch is configured by the large number of SOI-FETs, the increase in the by-chip occupied area due to the accumulated charge sink (ACS) of the P− region becomes a substantial large problem.

Furthermore, in the technology of eliminating the accumulated charge by the coupling of the accumulated charge sink (ACS) to the body, which has been described in the patent document 1, there is a possibility that the silicon substrate used as the support substrate will be brought to a floating state. It has thus been revealed by the study of the present inventors prior to the present invention that the potential of the support substrate becomes instable and the possibility that various adverse effects will occur in the high frequency characteristics of the antenna switch also exists.

The present invention has been made as a result of the above studies of the present inventors prior to the present invention.

It is thus an object of the present invention to reduce each harmonic component of an RF transmission output signal at an antenna switch.

It is another object of the present invention to make it unnecessary the addition of a manufacturing step to a silicon semiconductor manufacturing process and reduce an increase in by-chip occupied area.

It is a further object of the present invention to reduce a possibility that adverse effects will occur in the high frequency characteristics of an antenna switch.

The above and other objects and novel features of the present invention will be apparent from the description of the specification and the accompanying drawings.

A typical one of the inventive aspects of the invention disclosed in this application will be briefly described as follows:

A typical embodiment of the present invention is a semiconductor integrated circuit (110) equipped with an antenna switch (100) having a transmission switch (104), a reception switch (105), a transmission terminal (102), an input/output terminal (101), a reception terminal (103), a transmission control terminal (106) and a reception control terminal (107).

The transmission switch (104) includes transmission field effect transistors of which the source-to-drain current paths are coupled between the transmission terminal (102) and the input/output terminal (101) and the gate terminals are coupled to the transmission control terminal (106).

The reception switch (105) includes reception field effect transistors of which the source-to-drain current paths are coupled between the input/output terminal (101) and the reception terminal (103) and the gate terminals are coupled to the reception control terminal (107).

The transmission field effect transistors and the reception field effect transistors are respectively formed in a silicon-on-insulator structure comprised of silicon formed over the surface of an insulator formed over the surface of a silicon substrate used as a support substrate.

The semiconductor integrated circuit (110) is further equipped with a voltage generator (10) for generating a substrate voltage supplied to the silicon substrate.

The substrate voltage generated from the voltage generator (10) can be supplied to the silicon substrate used as the support substrate.

The level of the substrate voltage generated from the voltage generator is set to a value for reducing each harmonic component of the antenna switch (100) (refer to FIG. 1).

An advantageous effect obtained by a typical one of the inventive aspects of the invention disclosed in the present application will be briefly explained as follows:

According to the present invention, each harmonic component of an RF transmission output signal can be reduced at an antenna switch.

### BRIEF DESCRIPTION OF THE DRAWINGS

FIG. 1 is a diagram showing a configuration of a semiconductor integrated circuit 110 including an antenna switch 100 according to a first embodiment of the present invention;

FIG. 2 is a diagram illustrating a configuration of a cellular phone terminal according to a fourth embodiment of the present invention, which is equipped with an antenna switch ANT_SW;

FIG. 3 is a diagram depicting a configuration of a semiconductor integrated circuit 110 including an antenna switch 100 according to a second embodiment of the present invention;

FIG. 4 is a diagram showing the manner in which a transmission switch 104 and a reception switch 105 of the antenna switch 100 shown in FIG. 1 are respectively configured by an n-channel SOI-FET;

FIG. 5 is a diagram illustrating a configuration of a semiconductor integrated circuit 500 including an antenna switch 501 according to a third embodiment of the present invention;

FIG. 6 is a diagram showing a device structure of an SOI-MOSFET that configures an antenna switch examined by the present inventors prior to the present invention and is a diagram showing a device structure of each of both the n-channel SOI-FETs of the transmission switch 104 of the antenna switch 100 according to the first embodiment of the present invention shown in FIG. 1 and the n-channel SOI-FETs of the reception switch 105 thereof;

FIG. 7 is a diagram showing an equivalent circuit taken when a substrate voltage of a voltage generator 10 is supplied to a silicon substrate used as a support substrate having the device structure of the n-channel SOI-FET through a low-pass filter comprised of a resistor 11 and a capacitor 12 in the semiconductor integrated circuit 110 including the antenna switch 100 according to the first embodiment of the present invention shown in FIG. 1;

FIG. 8 is a diagram showing the voltage dependence of an off capacitance Coff where the present inventors have applied the technology of eliminating the accumulated charge by coupling of the accumulated charge sink to the body, which has been described in the patent document 1, to the SOI-MOSFET of the device structure shown in FIG. 6 prior to the present invention;

FIG. 9 is a diagram illustrating the voltage dependence of an off capacitance Coff where the technology of supplying the substrate voltage of the voltage generator 10 to the silicon substrate used as the support substrate of the SOI-MOSFET of the device structure according to the first embodiment of the present invention shown in FIG. 6 is applied; and

FIG. 10 is a diagram showing a configuration of a voltage generator 10 used for the antenna switch 100 according to the first embodiment of the present invention shown in FIG. 1 and the antenna switch 100 according to the second embodiment of the present invention shown in FIG. 3.

### DETAILED DESCRIPTION

### 1. Summary of the Embodiments

Summary of exemplary embodiments of the invention disclosed in the present application will first be explained. Reference numerals of the accompanying drawings referred to with parentheses in the description of the summary of the exemplary embodiments only illustrate elements included in the concept of components to which the reference numerals are given.

[1] A typical embodiment of the present invention is a semiconductor integrated circuit (110) equipped with an antenna switch (100) having a transmission switch (104), a reception switch (105), a transmission terminal (102), an input/output terminal (101), a reception terminal (103), a transmission control terminal (106) and a reception control terminal (107).

The transmission switch (104) includes transmission field effect transistors whose source-to-drain current paths are coupled between the transmission terminal (102) and the input/output terminal (101) and whose gate terminals are coupled to the transmission control terminal (106).

The reception switch (105) includes reception field effect transistors whose source-to-drain current path are coupled between the input/output terminal (101) and the reception terminal (103) and whose gate terminals are coupled to the reception control terminal (107).

Each of the transmission field effect transistors and the reception field effect transistors is formed by a silicon-on insulator structure comprised of silicon formed over the surface of an insulator formed over the surface of a silicon substrate used as a support substrate.

The semiconductor integrated circuit (110) is further equipped with a voltage generator (10) for generating a substrate voltage supplied to the silicon substrate.

The substrate voltage generated from the voltage generator (10) can be supplied to the silicon substrate used as the support substrate.

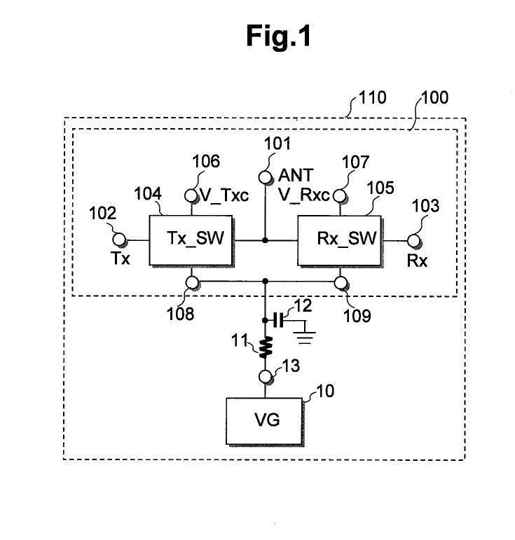

The level of the substrate voltage generated from the voltage generator is set to a value for reducing each harmonic component of the antenna switch (100) (refer to FIG. 1).

According to the foregoing embodiment, each harmonic component of an RF transmission output signal can be reduced at an antenna switch.

In a preferred embodiment, each of the transmission field effect transistors and the reception field effect transistors is an n-channel MOS transistor.

A semiconductor integrated circuit (110) according to another preferred embodiment is further equipped with a low-pass filter having a resistor (11) and a capacitor (12).

The substrate voltage generated from the voltage generator can be supplied to the silicon substrate used as the support substrate through the low-pass filter (11 and 12) (refer to FIG. 1).

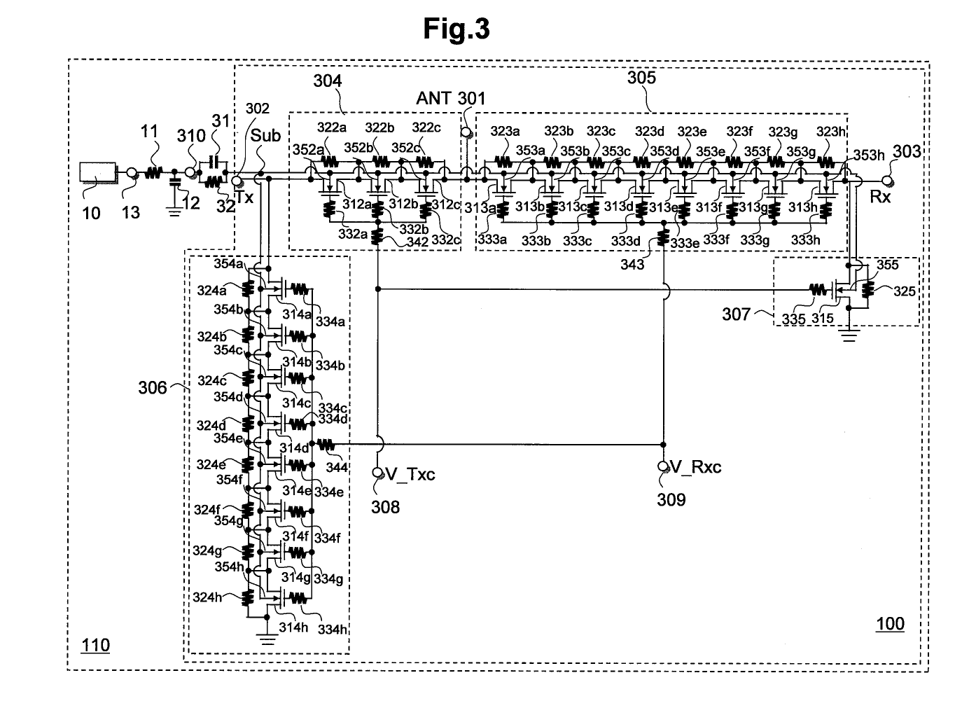

In a more preferred embodiment, the antenna switch (100), the voltage generator (10) and the low-pass filter (11 and 12) are monolithically integrated over the single silicon substrate of the silicon-on-insulator structure (refer to FIGS. 1 and 3).

In another more preferred embodiment, the antenna switch (501), the voltage generator (507) and the low-pass filter (505 and 506) are mounted onto a main surface of an insulation board (508) of the semiconductor integrated circuit (500) configured as a hybrid semiconductor integrated circuit (refer to FIG. 5).

In a concrete embodiment, the antenna switch (100) further has a transmission shunt switch (306) and a reception shunt switch (307).

The transmission shunt switch (306) includes transmission shunt field effect transistors (314a through 314h) whose source-to-drain current paths are coupled between the transmission terminal (302) and a ground potential and whose gate terminals thereof are coupled to the reception control terminal (309).

The reception shunt switch (307) includes a reception shunt field effect transistor (315) of which the source-to-drain current path is coupled between the reception terminal (303) and the ground potential and the gate terminal is coupled to the transmission control terminal (308).

The transmission shunt field effect transistors and the reception shunt field effect transistor are respectively formed in the silicon-on-insulator structure (refer to FIG. 3).

In a more concrete embodiment, the transmission switch (304), the reception switch (305) and the transmission shut switch (306) respectively include a plurality of field effect transistors whose source-to-drain current paths are coupled in series (refer to FIG. 3).

In another more concrete embodiment, the transmission switch (304), the reception switch (305) and the transmission shunt switch (306) respectively have resistors respectively coupled between the sources and drains of the respective field effect transistors whose source-to-drain current paths are coupled in series (refer to FIG. 3).

In a further concrete embodiment, the voltage generator (10) generates the substrate voltage according to the charge/discharge of a capacitor (82) responsive to a clock signal (CLK) (refer to FIG. 10).

In the most concrete embodiment, first capacitance-voltage dependence of a capacitance (1Cgs/2+Cds) of the sum of both a first series-coupled capacitance (1Cgs/2) of a source-to-gate MOS parasitic capacitance (Cgs) of each of the transistors and a gate-to-drain MOS parasitic capacitance (Cgd) thereof, and a source-to-drain parasitic capacitance (Cds) thereof due to a change in drain-to-source voltage (Vds) is substantially canceled out by second capacitance-voltage dependence of a second series-coupled capacitance (1Cbs/2) of a source-to-body parasitic capacitance (Cbs) of each of the transistors and a gate-to-body parasitic capacitance (Cdb) thereof due to a change in the drain-to-source voltage (Vds) according to the level of the substrate voltage generated from the voltage generator (refer to FIG. 9).

[2] A typical embodiment of another aspect of the present invention is a high frequency (i.e., radio frequency) module (RF_ML) equipped with both high frequency (i.e., radio frequency) power amplifiers (AMP1 and AMP2) and a semiconductor integrated circuit (110) having an antenna switch (100).

The antenna switch (100) has a transmission switch (104), a reception switch (105), a transmission terminal (102), an input/output terminal (101), a reception terminal (103), a transmission control terminal (106) and a reception control terminal (107).

An RF (Radio Frequency) transmission signal of each of the high frequency power amplifiers (AMP1 and AMP2) can be transferred from the transmission terminal (102) of the antenna switch (100) to the input/output terminal (101).

The transmission switch includes transmission field effect transistors whose source-to-drain current paths are coupled between the transmission terminal and the input/output terminal and whose gate terminals are coupled to the transmission control terminal.

The reception switch includes reception field effect transistors whose source-to-drain current paths are coupled between the input/output terminal and the reception terminal and whose gate terminals are coupled to the reception control terminal.

Each of the transmission field effect transistors and the reception field effect transistors is formed in a silicon-on-insulator structure comprised of silicon formed over the surface of an insulator formed over the surface of a silicon substrate used as a support substrate.

The semiconductor integrated circuit further has a voltage generator for generating a substrate voltage supplied to the silicon substrate.

The substrate voltage generated from the voltage generator can be supplied to the silicon substrate used as the support substrate.

The level of the substrate voltage generated from the voltage generator is set to a value for reducing each harmonic component of the antenna switch (refer to FIG. 1).

According to the foregoing embodiment, each harmonic component of an RF transmission output signal can be reduced at an antenna switch.

### 2. Further Detailed Description of the Embodiments

Preferred embodiments will next be explained in further details. Incidentally, in all the drawings for describing the best modes for implementing the invention, the same reference numerals are respectively attached to components having the same functions as those in the drawings, and their repetitive explanations will therefore be omitted.

### First Embodiment

<<Configuration of Semiconductor Integrated Circuit including Antenna Switch>>

FIG. 1 is a diagram showing a configuration of a semiconductor integrated circuit 110 including an antenna switch 100 according to a first embodiment of the present invention.

The antenna switch 100 shown in FIG. 1 configures an antenna switch of a single-pole double-throw (SPDT) type. In the field of the antenna switch, a common input/output terminal to which an antenna is coupled, is called “Single Pole”, and a reception terminal coupled to a receiving circuit and a transmission terminal coupled to a transmitting circuit are called “Throw”. Thus, in the antenna switch shown in FIG. 1, an input/output terminal 101 coupleable to an antenna mounted to a cellular phone terminal is referred to as “Single Pole”, and two terminals of a reception terminal 103 and a transmission terminal 102 are referred to as “Double Throw”.

The semiconductor integrated circuit 110 shown in FIG. 1 includes the antenna switch 100, a voltage generator 10, a resistor 11 and a capacitor 12. The antenna switch 100 shown in FIG. 1 includes the input/output terminal 101, the transmission terminal 102, the reception terminal 102, a transmission switch 104, a reception switch 105, a transmission control terminal 106, a reception control terminal 107 and substrate voltage supply terminals 108 and 109.

The semiconductor integrated circuit 110 shown in FIG. 1 is of a semiconductor integrated circuit having an SOI structure, in which a buried silicon dioxide film layer used as an insulator is formed over the surface of a silicon substrate used as a support substrate, and a large number of n-channel SOI-FETs are contained in a silicon layer formed over the surface of the buried silicon dioxide film layer. Further, the voltage generator 10, the resistor 11 and the capacitor 12 are integrated in the silicon layer.

Thus, the transmission switch 104 and the reception switch 105 of the antenna switch 100 shown in FIG. 1 are configured by n-channel SOI-FETs respectively. Source-to-drain current paths of n-channel SOI-FETs of the transmission switch 104 are coupled between the transmission terminal 102 and the input/output terminal 101. Source-to-drain current paths of n-channel SOI-FETs of the reception switch 105 are coupled between the input/output terminal 101 and the reception terminal 103. A gate electrode of each n-channel SOI-FET of the transmission switch 104 is coupled to the transmission control terminal 106. A gate electrode of each n-channel SOI-FET of the reception switch 105 is coupled to the reception control terminal 107. A substrate voltage generated from an output terminal 13 of the voltage generator 10 can be supplied to the substrate voltage supply terminals 108 and 109 of the silicon substrate used as the support substrate of the semiconductor integrated circuit 110 having the SOI structure in which the n-channel SOI-FETs of the transmission switch 104 and the n-channel SOI-FETs of the reception switch 105 are integrated, via a low-pass filter comprised of the resistor 11 and the capacitor 12.

### <<Transmission and Reception Operations by Antenna Switch>>

Since during the transmission operation by the antenna switch 100, a transmission control voltage signal of a high level is supplied to the transmission control terminal 106, and a reception control voltage signal of a low level is supplied o the reception control terminal 107, the n-channel SOI-FETs of the transmission switch 104 lying between the transmission terminal 102 and the input/output terminal 101 are respectively brought to an ON state, whereas the n-channel SOI-FETs of the reception switch 105 lying between the input/output terminal 101 and the reception terminal 103 are respectively brought to an OFF state.

Since during the reception operation by the antenna switch 100, a transmission control voltage signal of a low level is supplied to the transmission control terminal 106, and a reception control voltage signal of a high level is supplied o the reception control terminal 107, the n-channel SOI-FETs of the transmission switch 104 lying between the transmission terminal 102 and the input/output terminal 101 are respectively brought to an OFF state, whereas the n-channel SOI-FETs of the reception switch 105 lying between the input/output terminal 101 and the reception terminal 103 are respectively brought to an ON state.

### <<Configurations of Transmission Switch and Reception Switch>>

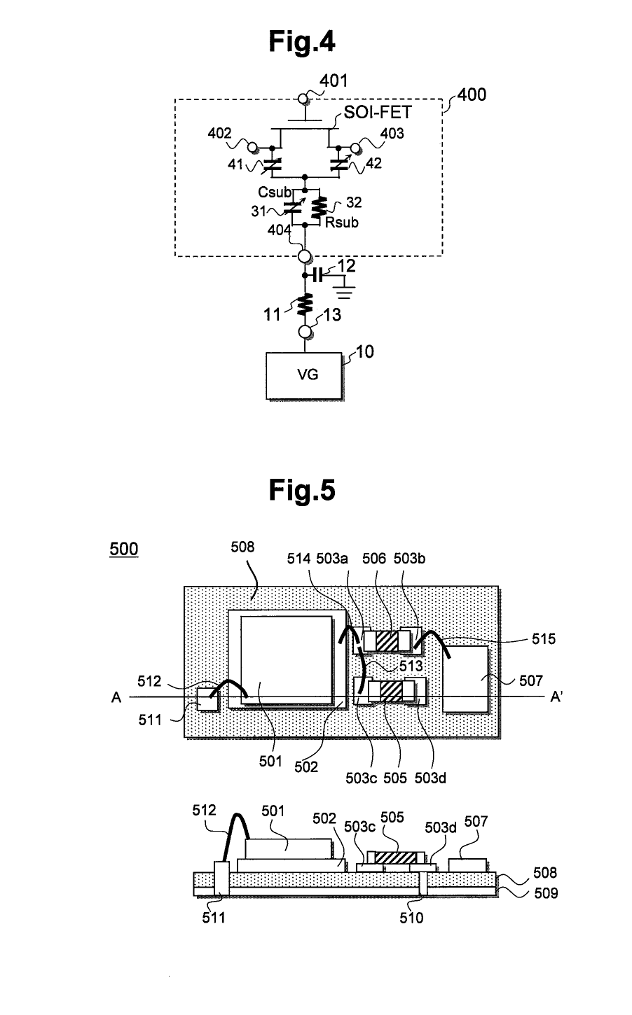

FIG. 4 is a diagram showing the manner in which the transmission switch 104 and reception switch 105 of the antenna switch 100 shown in FIG. 1 are respectively configured by an n-channel SOI-FET. In FIG. 4, a switch 400 operable even to both of the transmission switch 104 and the reception switch 105 includes an n-channel SOI-FET. A gate electrode 401 is coupleable to the transmission control terminal 106 or the reception control terminal 107, a source terminal 402 is coupleable to the transmission terminal 102 or the reception terminal 103, and a drain terminal 403 is coupleable to the input/output terminal 101. Further, the source terminal 402 and the drain terminal 403 are respectively coupled to one end of a parallel coupling of a substrate capacitor 31 (Csub) and a substrate resistor 32 (Rsub) through a source-to-substrate parasitic capacitor 41 (Cssub) and a drain-to-substrate parasitic capacitor 42 (Cdsub). The other end of the parallel coupling is coupled to a substrate voltage supply terminal 404. A substrate voltage generated from the corresponding voltage generator 10 can be supplied to the substrate voltage supply terminal 401 via a low-pass filter comprised of a resistor 11 and a capacitor 12.

### <<Device Structure of SOI-FET>>

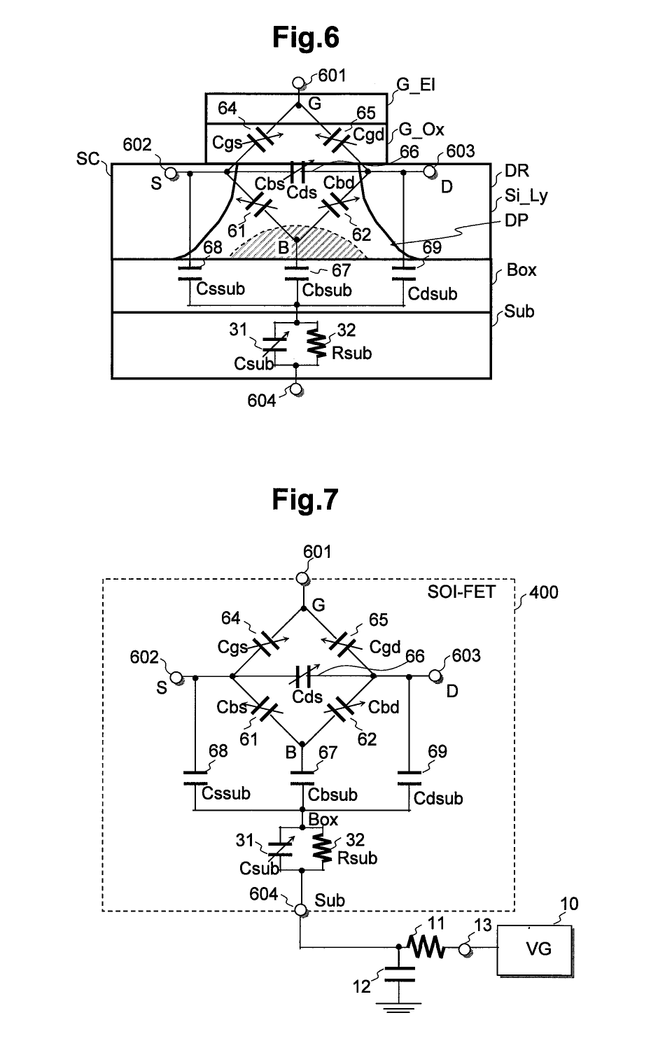

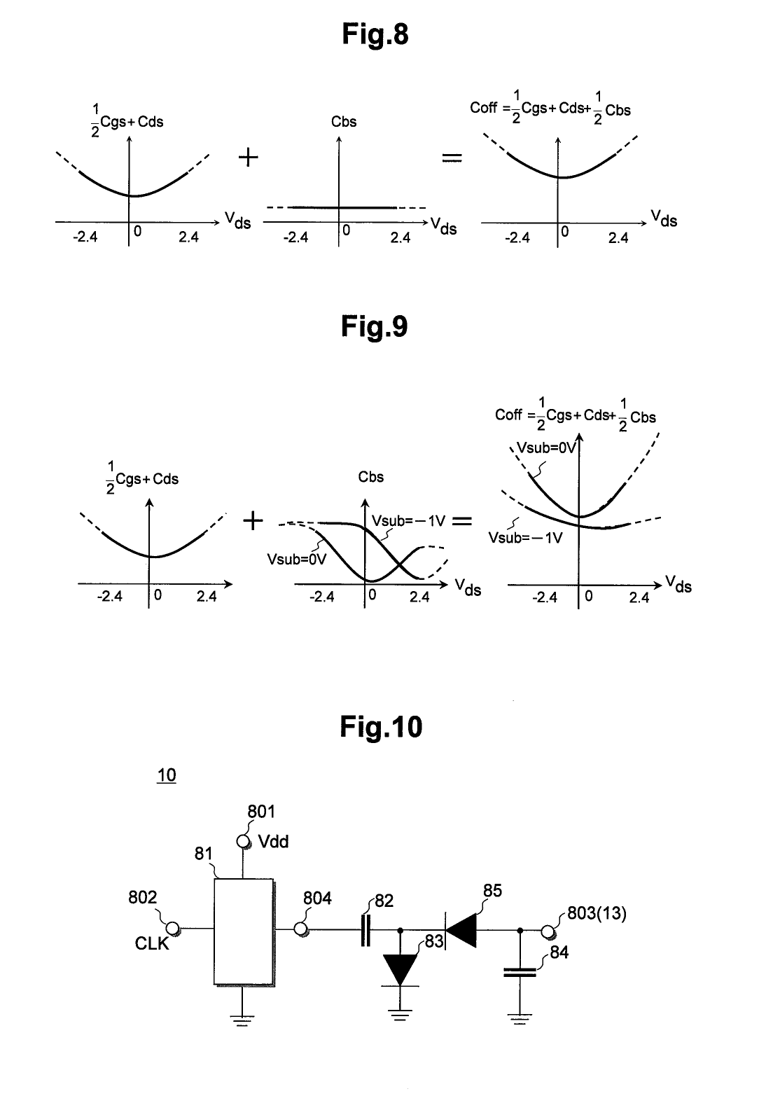

FIG. 6 is a diagram showing a device structure of each of the n-channel SOI-FETs for the transmission switch 104 and the n-channel SOI-FETs for the reception switch 105 in the antenna switch 100 according to the first embodiment of the present invention shown in FIG. 1.

In the SOI-FET shown in FIG. 6, a buried silicon dioxide film layer Box used as an insulator (I) is formed over the surface of a silicon substrate (Si)Sub used as a support substrate, and a silicon layer Si_Ly is formed over the surface (On) of the buried silicon dioxide film layer Box. In order to form the n-channel SOI-MOSFET, the silicon layer Si_Ly has been doped with an n-type dopant in low concentration from the beginning.

A gate oxide film G_Ox and a gate electrode G_EI of a polysilicon layer are patterned at the surface of the silicon layer Si_Ly. Thereafter, source and drain regions SC and DR of an n-type impurity region are formed in the silicon layer Si_Ly by ion implantation using an n-type dopant with the patterned gate oxide film G_Ox and gate electrode G_EI as masks. The p-type-doped silicon layer Si_Ly held by the source region SC and the drain region DR therebetween directly below the gate oxide film G_Ox functions as a body (B) also called “backgate”. A white portion DP of the body (B) is a depletion layer. Holes of carriers do not exist inside the depletion layer DP, but the nucleus of each ionized p-type dopant exists therein. Accordingly, a portion other than the depletion layer DP in the p-type-doped silicon layer Si_Ly held by the source region SC and the drain region DR therebetween directly underneath the gate oxide film G_Ox functions as an electrically neutral body (B). That is, the amount of a positive charge due to holes as carriers and the amount of a negative charge due to the nucleus of each ionized p-type dopant are balanced inside the electrically neutral body (B).

Thus, each of the n-channel SOI-FETs of the transmission switch 104 having the device structure of the n-channel SOI-FET shown in FIG. 6 and the n-channel SOI-FETs of the reception switch 105 having the same includes, as parasitic elements, the source-to-gate MOS parasitic capacitance Cgs, gate-to-drain MOS parasitic capacitance Cgd, source-to-drain parasitic capacitance Cds, source-to-body parasitic capacitance Cbs, body-to-drain parasitic capacitance Cbd, source-to-substrate parasitic capacitance Cssub, body (B)-to-substrate parasitic capacitance Cbsub, drain-to-substrate parasitic capacitance Cdsub, a substrate capacitor Csub, and a substrate resistor Rsub.

On the other hand, in the device structure of the n-channel SOI-FETs of the transmission switch 104 of the antenna switch 100 according to the first embodiment of the present invention shown in FIG. 6 and the n-channel SOI-FETs of the reception switch 105 thereof, the bias voltage due to the coupling of the accumulated charge sink (ACS) cannot be supplied to the body (B) and the body (B) is held floating, unlike the technology of eliminating the accumulated charge due to the coupling of the accumulated charged sink (ACS) to the body (B), which has been described in the patent document 1. As a result, there is no need to add manufacturing steps to a silicon semiconductor manufacturing process, thus making it possible to lighten an increase in the by-chip occupied area.

Further, in the device structure of each of the n-channel SOI-FETs of the transmission switch 104 of the antenna switch 100 according to the first embodiment of the present invention shown in FIG. 6 and the n-channel SOI-FETs of the reception switch 105 thereof, the stable substrate voltage generated from the voltage generator 10 can be supplied via the low-pass filter comprised of the resistor 11 and the capacitor 12 to the substrate voltage supply terminals 108 and 109 of the silicon substrate used as the support substrate of the semiconductor integrated circuit 110 having the SOI structure in which the n-channel SOI-FETs of the transmission switch 104 and the n-channel SOI-FETs of the reception switch 105 are integrated, unlike the floating state of the silicon substrate used as the support substrate of the device of each SOI-FET described in the patent document 1. Accordingly, it is possible to lighten the possibility that the adverse effect on the high frequency characteristics of the antenna switch will occur.

FIG. 7 is a diagram showing an equivalent circuit taken where in the semiconductor integrated circuit 110 including the antenna switch 100 according to the first embodiment of the present invention shown in FIG. 1, the substrate voltage of the voltage generator 10 is supplied to the silicon substrate used as the support substrate of the device structure of the n-channel SOI-FET shown in FIG. 6 via the low-pass filter comprised of the resistor 11 and the capacitor 12.

On the other hand, a high frequency input signal supplied from the antenna to the input/output terminal 101 used as a high frequency signal input terminal, of the antenna switch 110 shown in FIG. 1 is transferred to the reception terminal 103 through the reception switch 105. At this time, a high frequency signal component that leaks to each of the substrate voltage supply terminals 108 and 109, is bypassed to the ground potential via the capacitor 12 that functions as a bypass capacitor. The silicon substrate used as the support substrate of the device structure of the n-channel SOI-FET shown in FIG. 6 is brought to impedance relatively lower than a compound semiconductor substrate of high resistivity. Accordingly, if the capacitor 12 that functions as the bypass capacitor is not coupled to the substrate voltage supply terminals 108 and 109, the high frequency signal component that leaks to each of the substrate voltage supply terminals 108 and 109 leaks even to the silicon substrate, thereby increasing a loss in the high frequency signal.

On the other hand, in the low-pass filter comprised of the resistor 11 and the capacitor 12, the value of the resistive element 11 is set to a resistance value sufficiently larger than an antenna impedance 50Ω to reduce the loss in the high frequency signal. That is, the voltage generator 10 includes a large capacitor coupled between the output terminal 12 and the ground potential as will be explained with reference to FIG. 10 later. Thus, if the resistive element 11 set to the relatively large resistance is not coupled to the substrate voltage supply terminals 108 and 109 and the output terminal 13 of the voltage generator 10, the high frequency signal component that leaks to each of the substrate voltage supply terminals 108 and 109 leaks even to the large capacitor coupled to the output terminal 13 of the voltage generator 10, thereby increasing a loss in the high frequency signal.

### <<Voltage Dependence of Off Capacitance>>

FIG. 9 is a diagram showing the voltage dependence of the off capacitance Coff given by the above equation (1) where the technology of supplying the substrate voltage of the voltage generator 10 to the silicon substrate used as the support substrate of the SOI-MOSFET of the device structure according to the first embodiment of the present invention shown in FIG. 6.

The dependence of the capacitance of the sum of 1Cgs/2 of the firs term of the above equation (1) and Cds of the second term of the above equation (1) on a drain-to-source voltage Vds is shown on the left of FIG. 9. The capacitance of the sum becomes a minimum value when the drain-to-source voltage Vds is in the vicinity of zero volts, whereas the capacitance of the sum increases when the drain-to-source voltage Vds is in the vicinity of +2.4 volts or −2.4 volts. Since the cause of this mechanism has already been described above, it will be omitted.

The dependence on the drain-to-source voltage Vds, of the capacitance of a series coupling of both a source-to-body parasitic capacitance Cbs comprised of a source region SC of an n-type impurity region, a depletion layer DP and a body (B), corresponding to 1Cbs/2 of the third term of the above equation (1) and a body-to-drain parasitic capacitance Cbd comprised of the body (B), the depletion layer DP and a drain region DR of the n-type impurity region is shown in the center of FIG. 9.

First assume that the substrate voltage of the voltage generator 10 is in a state of being not supplied to the silicon substrate used as the support substrate of the SOI-MOSFET of the device structure according to the first embodiment of the present invention shown in FIG. 6 in a state in which no accumulated charge is generated in the channel region near the gate oxide film due to the gate bias voltage of the OFF-state SOI-MOSFET described in the patent document 1. When the drain-to-source voltage Vds is in the vicinity of zero volts in this state, the capacitance of the series coupling of the source-to-body parasitic capacitance Cbs and the body-to-drain parasitic capacitance Cbd becomes a minimum value, whereas the capacitance of the series coupling increases when the drain-to-source voltage Vds is in the vicinity of +2.4 volts or −2.4 volts, followed by reaching a saturated state. The cause of this mechanism is considered to be similar to the source-to-gate MOS parasitic capacitance Cgs and the gate-to-drain MOS parasitic capacitance Cgd.

Since the off capacitance Coff of the above equation (1) is determined by the sum total of both the capacitance of the sum of the first term 1Cgs/2 of the above equation (1) shown on the left of FIG. 9, and the second term Cds of the above equation (1), and the third term 1Cbs/2(Vsub=0V) of the above equation (1) shown in the center of FIG. 9 in the state in which the substrate voltage of the voltage generator 10 is not supplied to the silicon substrate, the voltage dependence of the off capacitance Coff(Vsub=0V) of the above equation (1) is shown on the right of FIG. 9.

In the off capacitance Coff(Vsub=0V) of the above equation (1) shown on the right of FIG. 9, the capacitance of the sum becomes a minimum value when the drain-to-source voltage Vds is in the vicinity of zero volts. On the other hand, when the drain-to-source voltage Vds is in the vicinity of +2.4 volts, the capacitance of the sum slightly increases, whereas when the drain-to-source voltage Vds is in the vicinity of −2.4 volts, the capacitance of the sum suddenly increases. Thus, since a large-amplitude transmission signal is applied to the reception switch circuit held in the OFF state during a transmission operation, and the off capacitance Coff increases with the increase in the drain-to-source voltage Vds, the harmonic distortion characteristic is degraded.

Therefore, the semiconductor integrated circuit 110 including the antenna switch 100 according to the first embodiment of the present invention shown in FIGS. 1, 6 and 7 makes it possible to adjust the level of the substrate voltage of the voltage generator 10, which is supplied to the silicon substrate used as the support substrate of the device structure of the n-channel SOI-FET via the low-pass filter comprised of the resistor 11 and the capacitor 12. For example, the substrate voltage generated from the voltage generator 10 is set to a voltage level of −1 volts.

That is, such a substrate voltage that the voltage dependence of the capacitance of the sum of the first term 1Cgs/2 of the above equation (1) shown on the left of FIG. 9 and the second term Cds thereof can be canceled out is selected. As a result, the voltage dependence of the capacitance is shifted in a positive voltage direction in the middle of FIG. 9 (refer to Vsub=−1V in the middle of FIG. 9).

Consequently, since the off capacitance Coff of the above equation (1) is determined by the sum total of the capacitance of the sum of the first term 1Cgs/2 of the above equation (1) shown on the left of FIG. 9 and the second term Cds thereof, and the third term 1Cbs/2(Vsub=−1V) of the above equation (1) shown in the middle of FIG. 9, the voltage dependence of the off capacitance Coff(Vsub=−1V) of the above equation (1) is shown on the right of FIG. 9.

As to the off capacitance Coff(Vsub=−1V) of the above equation (1) shown on the right of FIG. 9, the capacitance of the sum becomes a minimum value when the drain-to-source voltage Vds is in the vicinity of zero volts, whereas an increase in the off capacitance Coff is reduced to a negligible level even when the drain-to-source voltage Vds is in the vicinity of +2.4 volts or −2.4 volts, thereby making it possible to lighten the degradation of the harmonic distortion characteristic.

### Second Embodiment

<<Configuration of Semiconductor Integrated Circuit including another Antenna Switch>>

FIG. 3 is a diagram showing a configuration of a semiconductor integrated circuit 110 including an antenna switch 100 according to a second embodiment of the present invention.

The antenna switch 100 shown in FIG. 3 configures an antenna switch of a single-pole double-throw type in a manner similar to the antenna switch 100 shown in FIG. 1. In the antenna switch shown in FIG. 3, an input/output terminal 301 coupleable to an antenna mounted onto a cellular phone terminal is referred to as “Single Pole”, and two terminals of a reception terminal 303 and a transmission terminal 302 are referred to as “Double Throw”.

The semiconductor integrated circuit 110 shown in FIG. 3 includes the antenna switch 100, a voltage generator 10, a resistor 11 and a capacitor 12. The antenna switch 100 shown in FIG. 3 includes the input/output terminal 301, the transmission terminal 302, the reception terminal 303, a transmission switch 304, a reception switch 305, a transmission shunt switch 306, a reception shunt switch 307, a transmission control terminal 308, a reception control terminal 309 and a substrate voltage supply terminal 310.

The semiconductor integrated circuit 110 shown in FIG. 3 is of a semiconductor integrated circuit having an SOI structure, in which a buried silicon dioxide film layer used as an insulator is formed over the surface of a silicon substrate used as a support substrate, and a large number of n-channel SOI-FETs are contained in a silicon layer formed over the surface of the buried silicon dioxide film layer. Further, the voltage generator 10, the resistors 11 and 32 and the capacitors 12 and 31 are integrated in the silicon layer.

Accordingly, the transmission switch 304, the reception switch 305, the transmission shunt switch 306 and the reception shunt switch 307 of the antenna switch 100 shown in FIG. 3 are respectively configured by an n-channel SOI-FET.

Source-to-drain current paths of three series-coupled n-channel SOI-FETs 312a through 312c of the transmission switch 304 are coupled between the transmission terminal 302 and the input/output terminal 301. Source-to-drain current paths of eight series-coupled n-channel SOI-FETs 313a through 313h of the reception switch 305 are coupled between the input/output terminal 301 and the reception terminal 303.

Source-to-drain current paths of eight series-coupled n-channel SOI-FETs 314a through 314h of the transmission shunt switch 306 are coupled between the transmission terminal 302 and a ground potential. A source-to-drain current path of one n-channel SOI-FET 315 of the reception shunt switch 307 is coupled between the reception terminal 303 and the ground potential.

Gate electrodes of the three series-coupled n-channel SOI-FETs 312a through 312c of the transmission switch 304 are coupled to the transmission control terminal 308 via their corresponding gate resistors 332a through 332c and 342. A gate electrode of one n-channel SOI-FET 315 of the reception shunt switch 307 is coupled to the transmission control terminal 308 via its corresponding gate resistor 335. Gate electrodes of the eight series-coupled n-channel SOI-FETs 313a through 313h of the reception switch 305 are coupled to the reception control terminal 309 via their corresponding gate resistors 333a through 333h and 343. Gate electrodes of the eight series-coupled n-channel SOI-FETs 314a through 314h of the transmission shunt switch 306 are coupled to the reception control terminal 309 via their corresponding gate resistors 334a through 334h and 344.

The number of the transistors of the series coupling of the n-channel SOI-FETs of the transmission switch 304, reception switch 305, transmission shunt switch 306 and reception shunt switch 307 are set in such a manner that the n-channel SOI-FETs of the respective switches do not cause device destruction during transmission and reception operations. Further, in the transmission switch 304, the reception switch 305, the transmission shunt switch 306, and the reception shunt switch 307, dc potentials of the drains of the n-channel SOI-FETs and dc potentials of the sources thereof can respectively be set to approximately equal potentials by coupling the resistors between the drains and sources of the n-channel SOI-FETs.

### <<Transmission and Reception Operations by Antenna Switch>>

Since a transmission control voltage signal of a high level is supplied to the transmission control terminal 308 and a reception control voltage signal of a low level is supplied to the reception control terminal 309 during the transmission operation by the antenna switch 100 shown in FIG. 3, the three series-coupled n-channel SOI-FETs 312a through 312c of the transmission switch 304 provided between the transmission terminal 302 and the input/output terminal 301 are respectively brought to an ON state, whereas the eight series-coupled n-channel SOI-FETs 313a through 313h of the reception switch 305 provided between the input/output terminal 301 and the reception terminal 303 are respectively brought to an OFF state. At this time, the eight series-coupled n-channel SOI-FETs 314a through 314h of the transmission shunt switch 306 provided between the transmission terminal 302 and the ground potential are respectively brought to an OFF state. On the other hand, one n-channel SOI-FET 315 of the reception shunt switch 307 provided between the reception terminal 303 and the ground potential is brought to an ON state.

Since a transmission control voltage signal of a low level is supplied to the transmission control terminal 308 and a reception control voltage signal of a high level is supplied to the reception control terminal 309 during the reception transmission by the antenna switch 100 shown in FIG. 3, the three series-coupled n-channel SOI-FETs 312a through 312c of the transmission switch 304 provided between the transmission terminal 302 and the input/output terminal 301 are respectively brought to an OFF state, whereas the eight series-coupled n-channel SOI-FETs 313a through 313h of the reception switch 305 provided between the input/output terminal 301 and the reception terminal 303 are respectively brought to an ON state. At this time, the eight series-coupled n-channel SOI-FETs 314a through 314h of the transmission shunt switch 306 provided between the transmission terminal 302 and the ground potential are respectively brought to an ON state. On the other hand, one n-channel SOI-FET 315 of the reception shunt switch 307 provided between the reception terminal 303 and the ground potential is brought to an OFF state.

### <<Supply of Substrate Voltage to Silicon Substrate>>

A substrate voltage generated from the voltage generator 10 can be supplied to the substrate voltage supply terminal 310 of the silicon substrate used as the support substrate of the semiconductor integrated circuit 110 having the SOI structure in which all the n-channel SOI-FETs configuring the transmission switch 304, the reception switch 305, the transmission shunt switch 306 and the reception shunt switch 307 are integrated, via a low-pass filter comprised of the resistor 11 and capacitor 12. The substrate voltage supplied to the substrate voltage supply terminal 310 is supplied to its corresponding substrate Sub via the parallel coupling of the capacitor 31 and the resistor 32.

In the antenna switch 100 according to the second embodiment of the present invention shown in FIG. 3, a substrate Sub for the three series-coupled n-channel SOI-FETs 312a through 312c of the transmission switch 304 is indicated by substrate voltage supply wirings 352a through 352c. A substrate Sub for the eight series-coupled n-channel SOI-FETs 313a through 313h of the reception switch 305 is indicated by substrate voltage supply wirings 353a through 353h. A substrate Sub for the eight series-coupled n-channel SOI-FETs 314a through 314h is indicated by substrate voltage supply wirings 354a through 354h. A substrate Sub for one n-channel SOI-FET 315 of the reception shunt switch 307 is indicated by a substrate voltage supply wiring 355.

According to the antenna switch 100 according to the second embodiment of the present invention shown in FIG. 3, the degradation of a high frequency distortion characteristic can be reduced by the mechanism described in FIG. 9 in a manner similar to the antenna switch 100 according to the first embodiment of the present invention shown in FIGS. 1, 6 and 7.

### <<Configuration of Voltage Generator>>

FIG. 10 is a diagram showing the configuration of the voltage generator 10 used in the antenna switch 100 according to the first embodiment of the present invention shown in FIG. 1 and the antenna switch 100 according to the second embodiment of the present invention shown in FIG. 3.

The voltage generator 10 shown in FIG. 10 includes a power-supply voltage input terminal 801, a control signal input terminal 802, a voltage output terminal 803, a drive output terminal 804, a switching circuit 81, a first capacitor 82, a second capacitor 84, a first diode 83 and a second diode 85.

The power-supply voltage input terminal 801 of the switching circuit 81 is supplied with a power supply voltage Vdd, and the control signal input terminal 802 of the switching circuit 81 is supplied with a clock signal CLK having a predetermined frequency. A ground terminal of the switching circuit 81 is coupled to a ground potential, the drive output terminal 804 of the switching circuit 81 is coupled to one end of the first capacitor 82, and the other end of the first capacitor 82 is coupled to an anode of the first diode 83 and a cathode of the second diode 85. A cathode of the first diode 83 is coupled to the ground potential, an anode of the second diode 85 is coupled to the voltage output terminal 803 and one end of the second capacitor 84, and the other end of the second capacitor 84 is coupled to the ground potential. Incidentally, the clock signal CLK supplied to the control signal input terminal 802 of the switching circuit 81 can be generated by amplifying an RF carrier component of an RF transmission signal supplied to each of the transmission terminals 102 and 302 of the antenna switch 100 and thereafter performing waveform shaping thereof and the like.

### <<Operation of Voltage Generator>>

The operation of generating a negative voltage by the voltage generator 10 shown in FIG. 10 is as follows:

For example, the switching circuit 81 generates a high level drive output signal corresponding to the power supply voltage Vdd at the drive output terminal 804 in response to a high level clock signal CLK. Therefore, a charging current flows from the drive output terminal 804 to the ground potential via the first capacitor 82 and the first diode 83. When the forward voltage of the first diode 83 is assumed to be Vf, a voltage of Vdd−Vf is charged between both ends of the first capacitor 82.

Thereafter, the switching circuit 81 generates a low level drive output signal corresponding to the ground potential at the drive output terminal 804 in response to a low level clock signal CLK. Therefore, a discharging current flows from the ground potential to the ground potential via the second capacitor 84, the voltage output terminal 803, the second diode 85, the first capacitor 82 and the drive output terminal 804. In doing so, a coupling node of the other end of the first capacitor 82 and the cathode of the second diode 85 changes to a potential of −Vdd+Vf. When the forward voltage of the second diode 85 is also assumed to be Vf, the voltage output terminal 803 and one end of the second capacitor 84 are charged to a potential of −Vdd+2Vf.

Thus, the negative voltage is generated from the voltage output terminal 803(13) of the voltage generator 10 shown in FIG. 10. The negative voltage can be supplied to the silicon substrate Sub used as the support substrate of the semiconductor integrated circuit 110 having the SOI structure with the n-channel SOI-FETs integrated therein, via the low-pass filter comprised of the resistor 11 and the capacitor 12.

### Third Embodiment

<<Configuration of Semiconductor Integrated Circuit including another Antenna Switch>>

FIG. 5 is a diagram showing a configuration of a semiconductor integrated circuit 500 including an antenna switch 501 according to a third embodiment of the present invention.

The semiconductor integrated circuit 500 shown in FIG. 5 is different from the semiconductor integrated circuits 110 each having the monolithic SOI structure using the single silicon substrate, which have been described in the first and second embodiments described above. The semiconductor integrated circuit 500 is configured by a hybrid semiconductor integrated circuit called also “multi-chip module” in which a plurality of silicon substrates are mounted over an insulation board.

A planar structure of the hybrid semiconductor integrated circuit 500 is shown above FIG. 5, and a sectional structure of the hybrid semiconductor integrated circuit 500 is shown below FIG. 5. That is, a first semiconductor chip 501 for an antenna switch, a second semiconductor chip 507 for a voltage generator 10, and a capacitance chip 505 and a resistance chip 506 that configure a low-pass filter are respectively mounted over a main surface of the insulation board 508 of the hybrid semiconductor integrated circuit 500.

The first semiconductor chip 501 for the antenna switch of the semiconductor integrated circuit 500 shown in FIG. 5 corresponds to the antenna switch 100 described in each of the first and second embodiments. Thus, the first semiconductor chip 501 for the antenna switch includes an input/output terminal 301, a transmission terminal 302, a reception terminal 303, a transmission switch 304, a reception switch 305, a transmission shunt switch 306, a reception shunt switch 307, a transmission control terminal 308, a reception control terminal 309, and a substrate voltage supply terminal 310 in a manner similar to the antenna switch 100 shown in FIG. 3, for example. Further, the first semiconductor chip 501 for the antenna switch is a semiconductor integrated circuit having an SOI structure in a manner similar to the antenna switch 100 shown in FIG. 3, for example. In the first semiconductor chip 501, a buried silicon dioxide film layer used as an insulator is formed over the surface of a silicon substrate used as a support substrate, and a large number of n-channel SOI-FETs for configuring the antenna switch are contained in a silicon layer formed over the buried silicon dioxide film layer.

The second semiconductor chip 507 for the voltage generator 10 of the semiconductor integrated circuit 500 shown in FIG. 5 is equivalent to one in which a circuit configuration similar to the voltage generator 10 shown in FIG. 10, for example is integrated into a semiconductor chip of an SOI structure or a semiconductor chip for a bulk silicon substrate. In particular, a voltage generated from the second semiconductor chip 507 of the voltage generator 10 is supplied to one end of a bonding wire 515.

The capacitance chip 505 and the resistance chip 506 of the semiconductor integrated circuit 500 shown in FIG. 5 respectively correspond to the capacitor 12 and the resistor 11 for configuring the low-pass filter described in each of the first and second embodiments. Thus, the voltage of the other end of the bonding wire 515 is supplied to one end of the resistance chip 506 through a conductive land 503b, and the other end of the resistance chip 506 is coupled to a conductive land 503a. The conductive land 503a is coupled to one end of the capacitance chip 505 through a bonding wire 513 and a conductive land 503c, and the other end of the capacitance chip 505 is coupled to a back ground conductive layer 509 through a conductive land 503d and a conductive via hole 510. Further, the conductive land 503a is coupled to its corresponding silicon substrate used as the support substrate at the lower surface of the first semiconductor chip 501 having the SOI structure of the antenna switch through a bonding wire 514 and a conducive die pad 502. An internal ground wiring of the first semiconductor chip 501 of the antenna switch is coupled to the back ground conductive layer 509 via a bonding wire 512 and a conductive via hole 511. The back ground conductive layer 509 at the back surface of the insulation board 508 of the hybrid semiconductor integrated circuit 500 is coupleable to a ground electrode of a wiring board of a high frequency module with transmission RF power amplifiers built therein, using solder, conductive paste or the like.

### Fourth Embodiment

<<Cellular Phone Terminal Equipped with another Antenna Switch>>

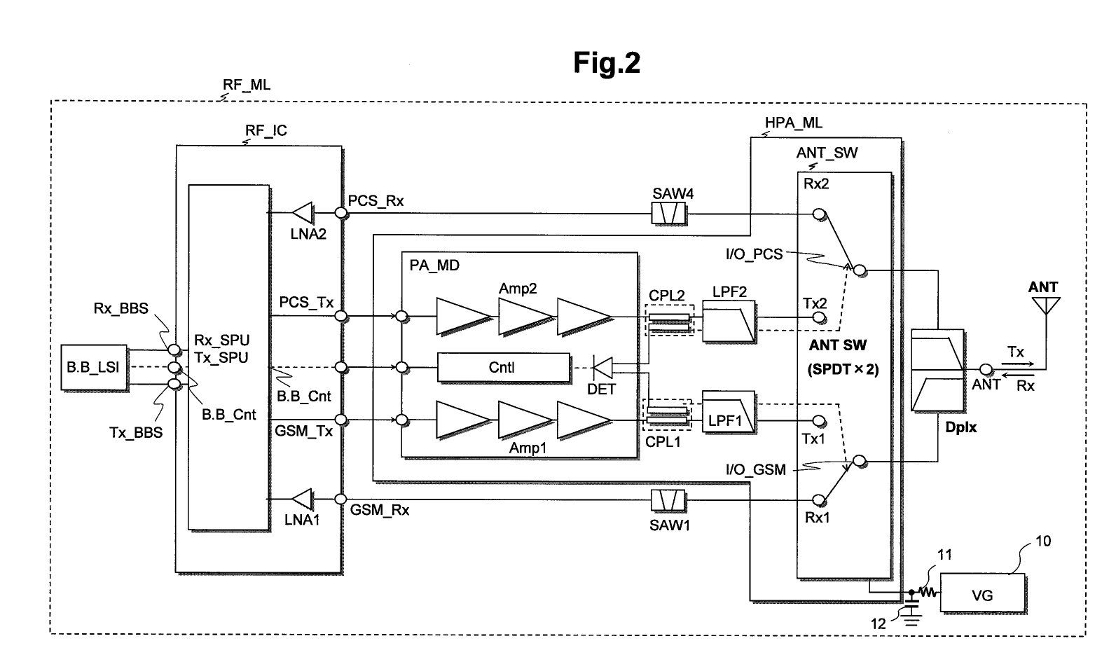

FIG. 2 is a diagram showing a configuration of a cellular phone terminal according to a fourth embodiment of the present invention, which is equipped with an antenna switch ANT_SW.

The cellular phone terminal shown in FIG. 2 includes an RF (Radio Frequency) module RF_ML. The RF module RF_ML includes a baseband signal processing unit B. B_LSI, an RF semiconductor integrated circuit RF_IC and a high power amplifier module HPA_ML. Further, the high power amplifier module HPA_ML includes a transmission RF power amplifier module PA_MD, power couplers CPL1 and CPL2, low-pass filters LPF1 and LPF2 and an antenna switch ANT_SW.

The baseband signal processing unit B. B_LSI supplies a transmission baseband signal Tx_BBS and a control signal B. B_Cnt to the RF semiconductor integrated circuit RF_IC. On the other hand, the RF semiconductor integrated circuit RF_IC supplies a reception baseband signal Rx_BBS to the baseband signal processing unit B. B_LSI.

A transmission signal processing unit Tx_SPU provided inside the RF semiconductor integrated circuit RF IC executes frequency upconversion of the transmission baseband signal Tx_BBS. With the frequency upconversion, a first RF transmission signal GSM_Tx of a low RF transmission frequency band (low band) or a second RF transmission signal PCS_Tx of a high RF transmission frequency band (high band) is generated. The first RF transmission signal GSM_Tx of the low band is amplified by a first RF power amplifier Amp1 of the transmission RF power amplifier module PA_MD, and the second RF transmission signal PCS_Tx of the high band is amplified by a second RF power amplifier Amp2 of the transmission RF power amplifier module PA_MD.

A first RF transmission power amplified signal of a low band at an output terminal of the first RF power amplifier Amp1 is supplied to a first transmission terminal Tx1 of the antenna switch ANT_SW through the first power coupler CPL1 and the first low-pass filter LPF1. A second RF transmission power amplified signal of a high band at an output terminal of the second RF power amplifier Amp2 is supplied to a second transmission terminal Tx2 of the antenna switch ANT_SW through the second power coupler CPL2 and the second low-pass filter LPF2. A first RF detection signal detected by the first power coupler CPL1 and a second RF detection signal detected by the second power coupler CPL2 are detected by a detector DET. A controller Cnt is able to control a first amplification gain of the first RF power amplifier Amp1 and a second amplification gain of the second RF power amplifier Amp2 in response to the detected output signal of the detector DET.

The antenna switch ANT_SW includes two SPDT type antenna switches. Each of the SPDT type antenna switches can use the antenna switch 100 according to the first embodiment of the present invention shown in FIG. 1, the antenna switch 100 according to the second embodiment of the preset invention shown in FIG. 3, or the antenna switch 501 according to the third embodiment of the present invention shown in FIG. 5. Accordingly, the antenna switch ANT_SW is configured by the semiconductor chip of the SOI structure, and the voltage generated from the voltage generator 10 is supplied to the silicon substrate used as the support substrate of the antenna switch ANT_SW having the SOI structure via the low-pass filter comprised of the resistor 11 and the capacitor 12. Incidentally, the voltage generator 10, the resistor 11 and the capacitor 12 can also be actually formed inside the high power amplifier module HPA_ML instead of inside the RF module RF_ML.

In a low band transmission mode of the cellular phone terminal, the first RF transmission power amplified signal of the low band supplied to the first transmission terminal Tx1 of the antenna switch ANT_SW is supplied to its corresponding antenna ANT of the cellular phone terminal via a first input/output terminal I/O_GSM and a duplexer Dp1x.

In a high band transmission mode of the cellular phone terminal, the second RF transmission power amplified signal of the high band supplied to the second transmission terminal Tx2 of the antenna switch ANT_SW is supplied to the antenna ANT of the cellular phone terminal via a second input/output terminal I/O_PCS and the duplexer Dplx.

In a low band reception mode of the cellular phone terminal, a first RF reception signal GSM_Rx received by the antenna ANT of the cellular phone terminal is amplified by a first low noise amplifier LNA1 provided inside the RF semiconductor integrated circuit RF_IC through the duplexer Dplx, the first input/output terminal I/O_GSM and the first reception terminal Rx1 of the antenna switch ANT_SW and a first surface acoustic wave filter SAW1. Accordingly, the low band RF reception signal corresponding to the output of the first low noise amplifier LNA1 is supplied to a reception signal processing unit Rx_SPU provided inside the RF semiconductor integrated circuit RF_IC. The reception signal processing unit Rx_SPU executes frequency downconversion of the low band RF reception signal and supplies a reception baseband signal Rx_BBS to the baseband signal processing unit B. B_LSI.

In a high band reception mode of the cellular phone terminal, a second RF reception signal PCS_Rx received by the antenna ANT of the cellular phone terminal is amplified by a second low noise amplifier LNA2 provided inside the RF semiconductor integrated circuit RF_IC through the duplexer Dplx, the second input/output terminal I/O_PCS and the second reception terminal Rx2 of the antenna switch ANT_SW and a second surface acoustic wave filter SAW2. Accordingly, the high band RF reception signal corresponding to the output of the second low noise amplifier LNA2 is supplied to the reception signal processing unit Rx_SPU provided inside the RF semiconductor integrated circuit RF_IC. The reception signal processing unit Rx_SPU executes frequency downconversion of the high band RF reception signal and supplies a reception baseband signal Rx_BBS to the baseband signal processing unit B. B_LSI.

The operation of switching between the transmission and reception operations of the antenna switch ANT_SW according to the fourth embodiment of the present invention shown in FIG. 2 can be controlled by the control signal B. B_Cnt supplied from the baseband signal processing unit B. B_LSI through the RF semiconductor integrated circuit RF_IC and the high power amplifier module HPA_ML.

While the invention made above by the present inventors has been described specifically on the basis of the various embodiments, the present invention is not limited to the embodiments. It is needless to say that the present invention may be modified in various ways within the scope not departing from the gist thereof.

For example, in the RF module RF_ML according to the fourth embodiment of the present invention shown in FIG. 2, RF power amplification MOS transistors for the first RF power amplifier Amp1 and the second RF power amplifier Amp2 of the transmission RF power amplifier module PA_MD can be integrated into the semiconductor chip of the SOI structure that configures the antenna switch ANT_SW.

At this time, the voltage generator 10, the resistor 11 and the capacitor 12 can further be integrated in the semiconductor chip of the SOI structure that configures the antenna switch ANT_SW.

Further, the clock signal CLK supplied to the control signal input terminal 802 of the switching circuit 81 of the voltage generator 10 shown in FIG. 10 may use a system clock signal supplied from the baseband signal processing unit B. B_LSI to a digital interface of the RF semiconductor integrated circuit RF_IC.

The semiconductor integrated circuit including the antenna switch according to the present invention, and the high frequency module with the semiconductor integrated circuit built therein are not limited to the cellular phone terminal, but may be applied even to a wireless LAN terminal.

What is claimed is:

1. A semiconductor integrated circuit including an antenna switch comprising:
a transmission switch;
a reception switch;
a transmission terminal;
an input/output terminal;
a reception terminal;
a transmission control terminal; and
a reception control terminal,
wherein the transmission switch comprises transmission field effect transistors of which the source-to-drain current paths are coupled between the transmission terminal and the input/output terminal and the gate terminals are coupled to the transmission control terminal,
wherein the reception switch comprises reception field effect transistors of which the source-to-drain current paths are coupled between the input/output terminal and the reception terminal and the gate terminals are coupled to the reception control terminal,
wherein the transmission field effect transistors and the reception field effect transistors are respectively formed in a silicon-on-insulator structure comprising silicon formed over a surface of an insulator formed over a surface of a silicon substrate used as a support substrate,
wherein the semiconductor integrated circuit further comprises a voltage generator for generating a substrate voltage supplied to the silicon substrate,
wherein the substrate voltage generated from the voltage generator is capable of being supplied to the silicon substrate used as the support substrate, and
wherein the level of the substrate voltage generated from the voltage generator is set to a value for reducing each harmonic component of the antenna switch.

2. The semiconductor integrated circuit according to claim 1,
wherein each of the transmission field effect transistors and the reception field effect transistors is an n-channel MOS transistor.

3. The semiconductor integrated circuit according to claim 2, further comprising:
a low-pass filter comprising a resistor and a capacitor,
wherein the substrate voltage generated from the voltage generator is capable of being supplied to the silicon substrate used as the support substrate via the low-pass filter.

4. The semiconductor integrated circuit according to claim 3,
wherein the antenna switch, the voltage generator and the low-pass filter are monolithically integrated over the single silicon substrate of the silicon-on-insulator structure.

5. The semiconductor integrated circuit according to claim 3,
wherein the antenna switch, the voltage generator and the low-pass filter are mounted onto a main surface of an insulation board of the semiconductor integrated circuit configured as a hybrid semiconductor integrated circuit.

6. The semiconductor integrated circuit according to claim 3,
wherein the antenna switch further comprises a transmission shunt switch and a reception shunt switch,
wherein the transmission shunt switch comprises transmission shunt field effect transistors of which the source-to-drain current paths are coupled between the transmission terminal and a ground potential and the gate terminals are coupled to the reception control terminal,
wherein the reception shunt switch comprises a reception shunt field effect transistor of which the source-to-drain current path is coupled between the reception terminal and the ground potential and the gate terminal is coupled to the transmission control terminal, and
wherein the transmission shunt field effect transistors and the reception shunt field effect transistor are respectively formed in the silicon-on-insulator structure.

7. The semiconductor integrated circuit according to claim 6,
wherein each of the transmission switch, the reception switch and the transmission shunt switch comprises a plurality of field effect transistors of which the source-to-drain current paths are coupled in series.

8. The semiconductor integrated circuit according to claim 7,
wherein in the transmission switch, the reception switch and the transmission shunt switch, resistors are respectively coupled between sources and drains of the field effect transistors of which the source-to-drain current paths are coupled in series.

9. The semiconductor integrated circuit according to claim 7,
wherein the voltage generator generates the substrate voltage according to charge/discharge of a capacitor responsive to a clock signal.

10. The semiconductor integrate circuit according to claim 7,
wherein first capacitance-voltage dependence of a capacitance of the sum of both a first series-coupled capacitance of a source-to-gate MOS parasitic capacitance of each of the transistors and a gate-to-drain MOS parasitic capacitance thereof, and a source-to-drain parasitic capacitance thereof due to a change in drain-to-source voltage is substantially canceled out by second capacitance-voltage dependence of a second series-coupled capacitance of both a source-to-body parasitic capacitance of each of the transistors and a gate-to-body parasitic capacitance thereof due to a change in drain-to-source voltage according to the level of the substrate voltage generated from the voltage generator.

11. A radio frequency module comprising:
a plurality of radio frequency power amplifiers; and
a semiconductor integrated circuit comprising an antenna switch,
wherein the antenna switch comprises a transmission switch, a reception switch, a transmission terminal, an input/output terminal, a reception terminal, a transmission control terminal and a reception control terminal,
wherein an RF transmission signal of each of the high frequency power amplifiers is capable of being transferred from the transmission terminal of the antenna switch to the input/output terminal,
wherein the transmission switch comprises transmission field effect transistors of which the source-to-drain current paths are coupled between the transmission terminal and the input/output terminal and the gate terminals are coupled to the transmission control terminal,
wherein the reception switch comprises reception field effect transistors of which the source-to-drain current paths are coupled between the input/output terminal and the reception terminal and the gate terminals are coupled to the reception control terminal,
wherein the transmission field effect transistors and the reception field effect transistors are respectively formed in a silicon-on insulator structure comprised of silicon formed over a surface of an insulator formed over a surface of a silicon substrate used as a support substrate,
wherein the semiconductor integrated circuit further comprises a voltage generator for generating a substrate voltage supplied to the silicon substrate,
wherein the substrate voltage generated from the voltage generator is capable of being supplied to the silicon substrate used as the support substrate, and
wherein the level of the substrate voltage generated from the voltage generator is set to a value for reducing each harmonic component of the antenna switch.

12. The radio frequency module according to claim 11,
wherein each of the transmission field effect transistors and the reception field effect transistors is an n-channel MOS transistor.

13. The radio frequency module according to claim 12, further comprising:
a low-pass filter comprising a resistor and a capacitor,
wherein the substrate voltage generated from the voltage generator is capable of being supplied to the silicon substrate used as the support substrate via the low-pass filter.

14. The radio frequency module according to claim 13,
wherein the antenna switch, the voltage generator and the low-pass filter are monolithically integrated over the signal silicon substrate of the silicon-on-insulator structure.

15. The radio frequency module according to claim 13,
wherein the antenna switch, the voltage generator and the low-pass filter are mounted onto a main surface of an insulation board of the semiconductor integrated circuit configured as a hybrid semiconductor integrated circuit.

16. The radio frequency module according to claim 13,
wherein the antenna switch further comprises a transmission shunt switch and a reception shunt switch,
wherein the transmission shunt switch comprises transmission shunt field effect transistors of which the source-to-drain current paths are coupled between the transmission terminal and a ground potential and the gate terminals are coupled to the reception control terminal,
wherein the reception shunt switch comprises reception shunt field effect transistors of which the source-to-drain current paths are coupled between the reception terminal and the ground potential and the gate terminals are coupled to the transmission control terminal, and
wherein the transmission shunt field effect transistors and the reception shunt field effect transistors are respectively formed in the silicon-on-insulator structure.

17. The radio frequency module according to claim 16,
wherein each of the transmission switch, the reception switch and the transmission shunt switch comprises a plurality of field effect transistors whose source-to-drain current paths are coupled in series.

18. The radio frequency module according to claim 17,
wherein in the transmission switch, the reception switch and the transmission shunt switch, resistors are respectively coupled between sources and drains of the field effect transistors of which the source-to-drain current paths are coupled in series.

19. The radio frequency module according to claim 17,
wherein the voltage generator generates the substrate voltage according to charge/discharge of a capacitor responsive to a clock signal.

20. The radio frequency module according to claim 17,
wherein first capacitance-voltage dependence of a capacitance of the sum of both a first series-coupled capacitance of a source-to-gate MOS parasitic capacitance of each of the transistors and a gate-to-drain MOS parasitic capacitance thereof, and a source-to-drain parasitic capacitance thereof due to a change in drain-to-source voltage is substantially canceled out by second capacitance-voltage dependence of a second series-coupled capacitance of both a source-to-body parasitic capacitance of each of the transistors and a gate-to-body parasitic capacitance thereof due to a change in drain-to-source voltage according to the level of the substrate voltage generated from the voltage generator.
